(19) United States
(12) Patent Application Publication
(10) Pub. No.: US 2026/0172048 A1
(43) Pub. Date: Jun. 18, 2026

(54) MODULAR AND SCALABLE HIGH PERFORMANCE COMPRESSION

(71) Applicant: XILINX, INC., San Jose, CA (US)

(72) Inventors: Durga Neeraj KOIDALA, Hyderabad (IN); Sebastian TURULLOLS, Los Altos, CA (US); Robert Bellarmin SUSAI, Hyderabad (IN); Vishnu CHEERAKODA, Hyderabad (IN); Rohit Kumar SHARMA, Hyderabad (IN); Jamon BOWEN, Longmont, CO (US)

(21) Appl. No.: 18/981,106

(22) Filed: Dec. 13, 2024

(51) Int. Cl. H03M 7/30

(52) U.S. Cl. CPC H03M 7/6082; H03M 7/6011

(57) ABSTRACT

A modular and scalable high-performance compression system includes multiple compression units (CUs), each including a compression circuit, an input buffer, and a history buffer, and further including input circuitry that loads the input buffers and the history buffers with sub-blocks of data blocks. The compression circuits identify segments of the sub-blocks of the corresponding input buffers that match segments of the sub-blocks of the corresponding history buffers, and encode the identified segments based on positions/offsets of the matching segments within the history buffers. The system may include multiple selectable compression modes, and may compress multiple data blocks in parallel, based on the same or differing compression modes. The compression modes may include a high throughput mode and a high compression ratio mode, and may further include dynamic selection mode that selects a compression mode based on a compression ratio, available resources, and/or other criteria.

### TECHNICAL FIELD

Examples of the present disclosure generally relate to data compression and, more particularly, to modular and scalable high performance data compression solutions.

### BACKGROUND

Data compression is employed in a wide variety of applications, including data centers, content streaming services, and others. As demands for data storage increase, demands on data compression also increase.

### SUMMARY

Techniques for modular and scalable high performance data compression solutions are described. One example is a data compression system that includes multiple compression units (CUs), each including a compression circuit, an input buffer, and a history buffer. The data compression system further includes input circuitry that loads the input buffers and the history buffers with sub-blocks of a data block. The compression circuits identify segments of the sub-blocks of the corresponding input buffers that match segments of the sub-blocks of the corresponding history buffers, and one or more of the compression circuits encodes the identified segments based on positions/offsets of the matching segments within the respective history buffers.

Another example described herein is method that includes compressing a data block with a data compression system that includes multiple compression units (CUs), each including a compression circuit, an input buffer, and a history buffer, where the compressing includes selecting one of multiple data compression modes, loading the input buffers and the history buffers with sub-blocks of the data block, identifying segments of the sub-blocks of the input buffers that match segments of the sub-blocks of the corresponding history buffers, by the corresponding compression circuits, and encoding the identified segments based on positions/offsets of the matching segments within the respective history buffers, by one or more of the compression circuits.

Another example described herein is a system that includes a host processor that executes an application program, a data compression device that compresses data associated with the application program, and a data storage device that stores the compressed data. The data compression device includes multiple compression units (CUs), each including a compression circuit, an input buffer, and a history buffer. The data compression device further includes input circuitry that loads the input buffers and the history buffers with sub-blocks of a data block based on one of multiple selectable data compression modes.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A depicts a data compression system, according to an embodiment.

FIG. 1B depicts the system of FIG. 1A, further including control circuitry that selects and/or controls data compression modes.

FIG. 2 depicts the system of FIG. 1A in a throughput mode, according to an embodiment.

FIGS. 3A through 3H depict the system of FIG. 1A at respective stages or operations of the throughput mode, according to an embodiment.

FIGS. 4A through 4H depict system the system of FIG. 1A at respective stages or operations of a compression ratio mode, according to an embodiment.

FIGS. 5A, 5B, and 5C depict a method of compressing data, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe modular and scalable high performance data compression solutions.

Data compression techniques include high compression ratio techniques that prioritize reduction of file size over throughput and latency, and high-throughput techniques that prioritize low-latency over compression ratio.

Data compression may be performed by a host system executing an application program, or may be offloaded to an accelerator circuit. The former may incur significant latency. The latter may incur additional hardware costs and power consumption.

Data compression solutions disclosed herein include in-line hardware-based circuitry (e.g., an in-line pipelined circuit and/or an accelerator circuit), that supports multiple data compression modes.

The multiple data compression modes may include, for example and without limitation, a low latency high-throughput mode (hereinafter, “throughput mode”), a high-compression ratio mode (hereinafter, “compression ratio” mode), and/or a dynamic selection mode that intelligently select amongst multiple compression modes without user intervention. The throughput mode may be useful for situations/applications that demand low latency/higher throughput. The compression ratio mode may be useful for situations/applications that demand higher compression ratios and/or are more tolerant with respect to latency/throughput (e.g., applications involving significant amounts of data, large file sizes, and/or data archival).

The dynamic selection mode may be useful to balance throughput and compression ratios. The dynamic selection mode may balance throughput and compression ratios based on one or more of a variety of criteria such as, without limitation, resource availability, file types, data sources (e.g., different modes for different users/customers), and/or other criteria. In an example, the dynamic selection mode switches from the compression ratio mode to the throughput mode when the compression ratio is below a threshold (e.g., when the compression ratios are not sufficiently high to justify potential added latency of the compression ratio mode). In another example, dynamic selection mode switches from the compression ratio mode to the throughput mode, or from the throughput mode to the compression ratio mode based on resource availability (e.g., switch to throughput mode when resources are constrained).

Data compression solutions disclosed herein may use the same hardware resources for the multiple modes, and may thus be useful as an area-efficient solution and/or a power-efficient solution.

Data compression solutions disclosed herein may be seamlessly integrated into systems with high data flows and/or varying data flows.

Data compression solutions disclosed herein may be useful to meet in-line performance demands with minimal resource utilization.

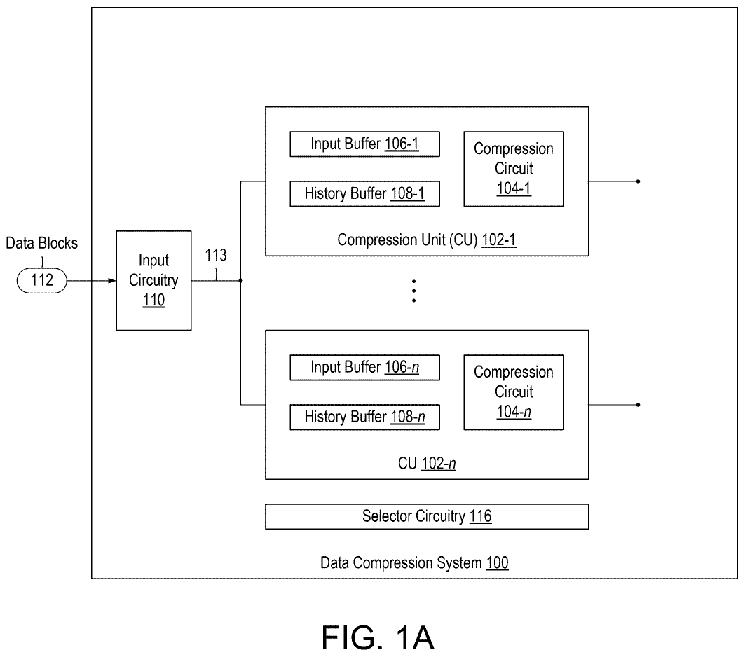

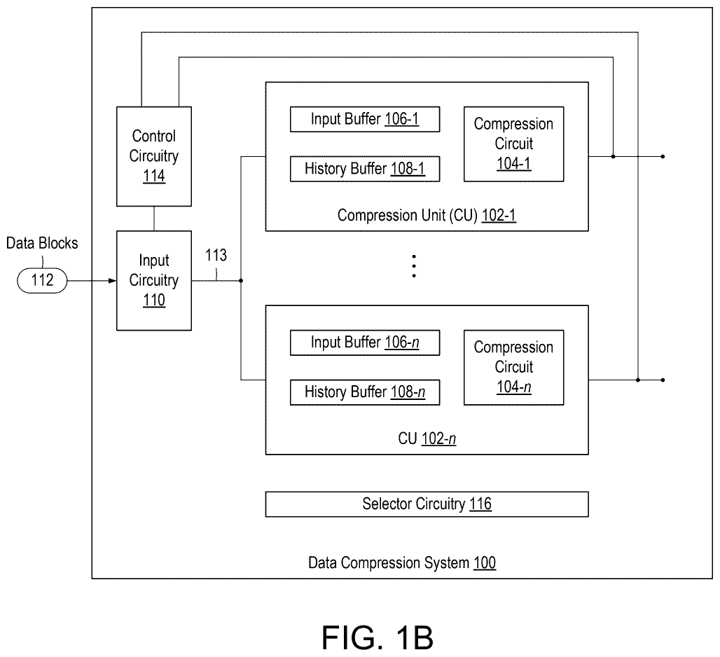

FIG. 1A depicts a data compression system (system) 100, according to an embodiment. System 100 includes compression units 102-1 through 102-n (collectively, compression units 102), that compress sub-blocks 113 of data blocks 112. CUs 102 include respective compression circuits 104, input buffers 106, and history buffers 108. Compression circuits 104 may include hardware (e.g., logic, look-up tables, and/or other circuitry), and/or a processor that executes instructions stored in memory. System 100 may be implemented as a circuit block within an integrated circuit device, such as an integrated circuit die/chip and/or or a multi-die package.

CUs 102 may serve as dictionary encoders, which may also be referred to as substitution encoders. A dictionary encoder searches for matches between a segment of data to be compressed, and strings or segments of data contained in a data structure referred to as a dictionary. When the dictionary encoder finds a match, the dictionary encoder encodes or replaces the segment with the position/offset of the matching segment/string in the dictionary.

In the example of FIG. 1A, input buffers 106 may be loaded with sub-blocks 113 for compression, and history buffers 108 may serve as dictionaries. In this example, compression circuits 104 may encode/substitute segments of sub-blocks 113 of input buffers 106 based on positions/offsets of matching segments in respective history buffers 108.

System 100 may further include input circuitry 110 that loads sub-blocks 113 into input buffers 106 (i.e., as data to be compressed), and into history buffers 108 (i.e., as dictionary data). Input circuitry 110 may receive data blocks 112 as streaming data, and input circuitry 110 or other circuitry may segment data blocks 112 into sub-blocks 113. Input circuitry 110 may segment data blocks 112 into sub-blocks 113 based on depths (i.e., sizes/capacities) of input buffers 106 and history buffers 108. Alternatively, or additionally, depths of input buffers 106 and history buffers 108 may be configurable/selectable based on sizes of sub-blocks 113.

System 100 may be operable in one or more modes. System 100 may be operable in a performance or throughput mode in which CUs 102 match segments of respective sub-blocks 113 with segments of the respective sub-blocks, and encode the matching segments independent of one another. In other words, sub-blocks 113 are directed to different CUs 102 for parallel processing, which may provide high performance/throughput and low latency.

Alternatively, or additionally, system 100 may be operable in a compression ratio mode in which multiple CUs 102 cooperate to match segments of a sub-block 113 to segments of multiple sub-blocks of the same data block 112. Selector circuitry 116 may select match results of one of the CUs 102 for encoding. Selector circuitry 116 may be included within one or more CUs 102, or may be distributed amongst multiple CUs 102. System 100 may be operable in multiple user selectable modes and/or in a dynamic selection mode, such as described below with reference to FIG. 1B.

The compression ratio mode essentially expands overall match engine capacity by augmenting individual match engines coming from each CU. The best match across the multiple CUs 102 is encoded, and the CUs are initialized to the same level for the next match search. In examples below, four CUs 102 are brought together to process data blocks 112A and 112B. In an example, data blocks 112A and 112B are 32 KB each, and sub-blocks 113 are 8 KB. In this example, each of the four CUs 102 has an 8 KB sub-block in the corresponding history buffer 108, the combined nature of the four history buffers 108 effectively serves as a 32 KB history buffer, which may provide a higher compression relative to the throughput mode (i.e., because it is more likely to find longer matches in a 32 KB history than an 8 KB history). Data blocks 112 are not limited to 32 KB, and sub-blocks 113 are not limited to four sub-blocks or 8 KB.

FIG. 1B depicts system 100, further including control circuitry 114 that selects and/or controls data compression modes of system 100. Control circuitry 114 may operate based on user input and/or may operate in a dynamic selection mode in which control circuitry 114 selects a mode based on one or more criteria. Control circuitry 114 may select the throughput mode by default, and may dynamically switch to the compression ratio mode based the one or more criteria. In an example, control circuitry 114 monitors a compression ratio of one or more prior data blocks 112, switches to the compression ratio mode if the compression ratio is below a threshold.

Control circuitry 114 may control and/or configure input circuitry 110 to load input buffers 106 and history buffers 108 based on a selected mode. Control circuitry 114 may also determine and/or select a number of CUs 102 for compressing a data block 112. In an example, control circuitry 114 may configure input circuitry 110 and a first set of CUs 102 to compress one or more data blocks 112 in the throughput mode, and may configure input circuitry 110 and a second set of CUs 102 to compress one or more other data blocks 112 in the compression ratio mode. In this example, the first and second sets of CUs 102 may compress the respective data blocks 112 based on the respective modes, in parallel with one another.

In an example, control circuitry 114 monitors compression ratios of CUs 102 (e.g., over multiple data blocks 112), and may change the mode and/or other parameters (e.g., numbers of sub-blocks per block, sub-block size, buffer depths, and/or numbers of CUs to employ per data block 112). Control circuitry 114 may, for example, switch from the compression ratio mode to the throughput mode when the compression ratios are below a threshold (i.e., when the compression ratios are not sufficiently high to justify the potential added latency of the compression ratio mode). Alternatively, or additionally, control circuitry 114 may switch from the compression ratio mode to the throughput mode, or from the throughput mode to the compression ratio mode based on availability of CUs 102 (e.g., may select throughput mode when availability of CUs 102 is constrained).

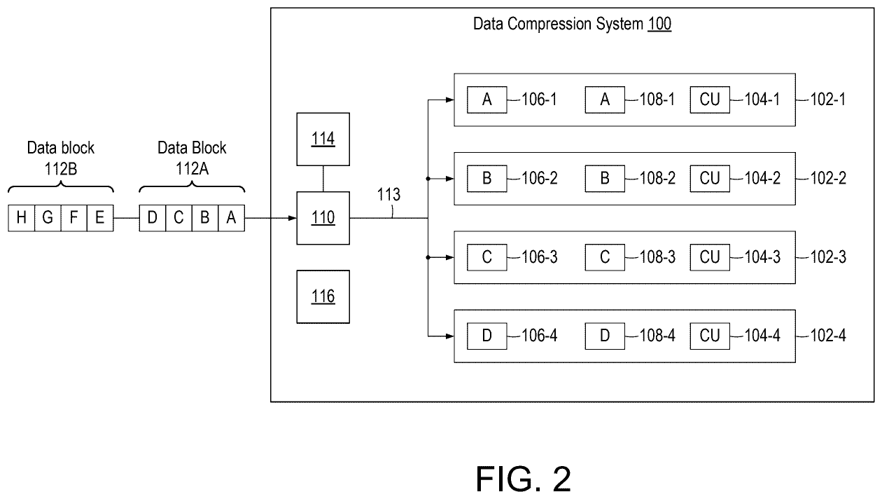

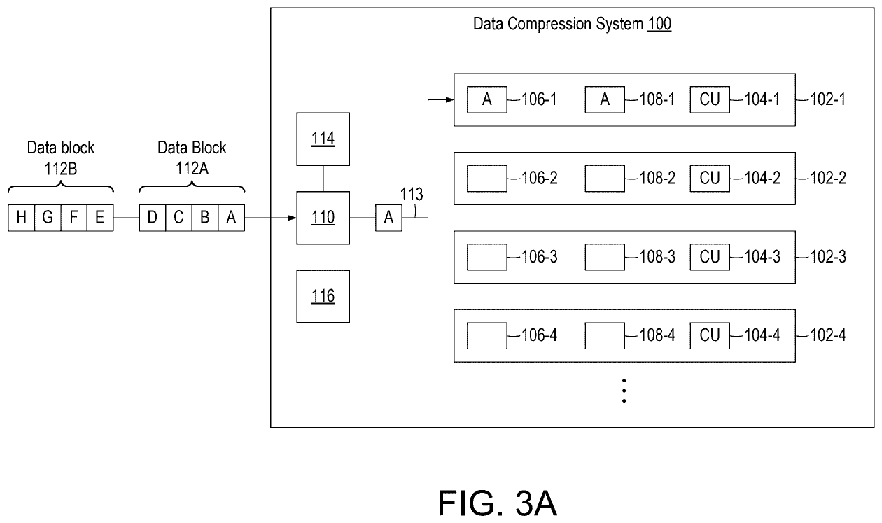

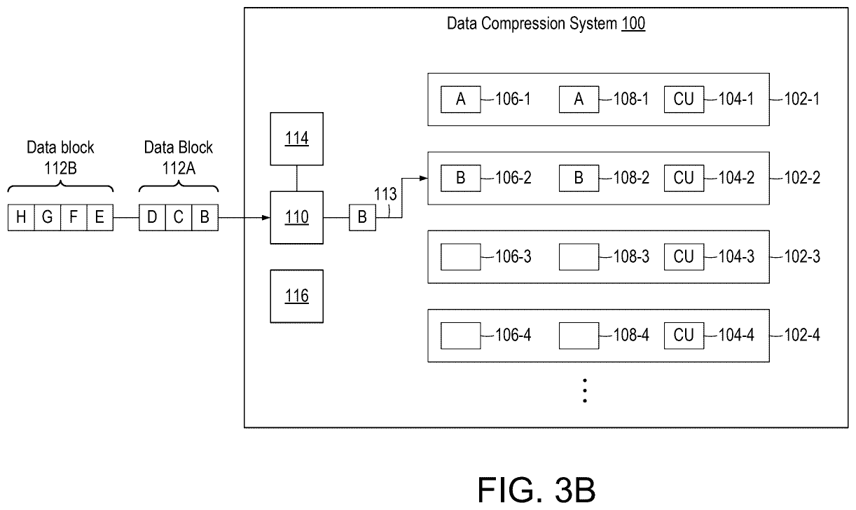

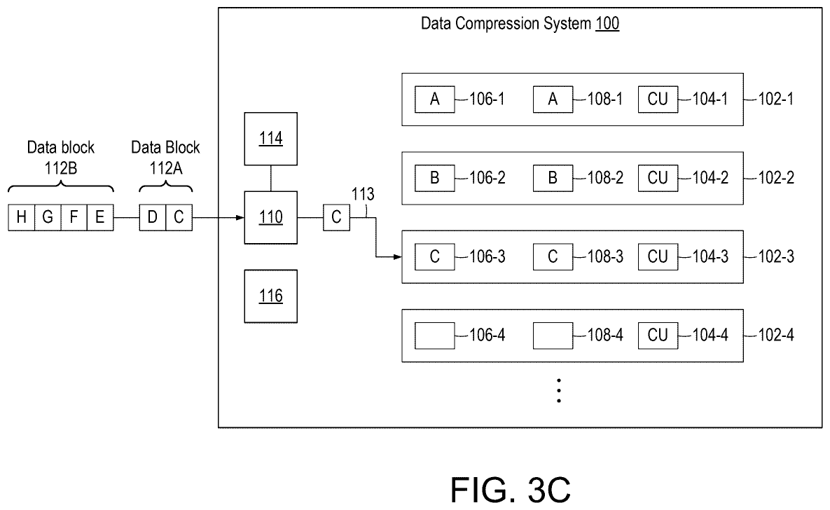

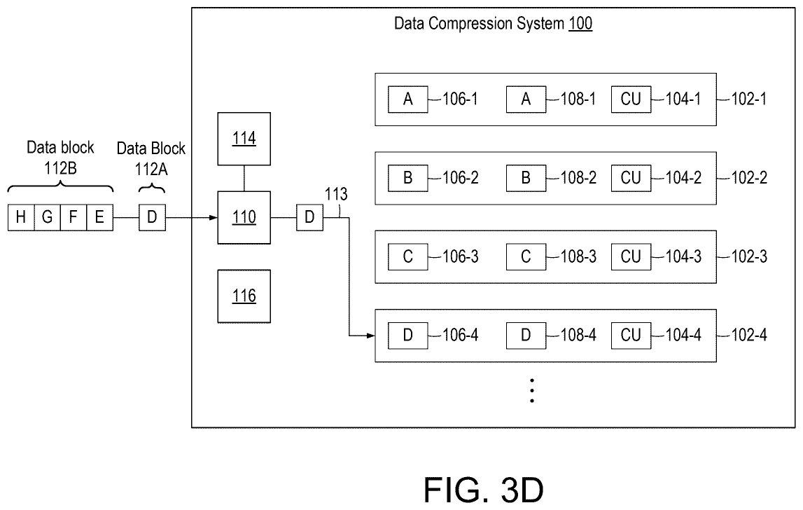

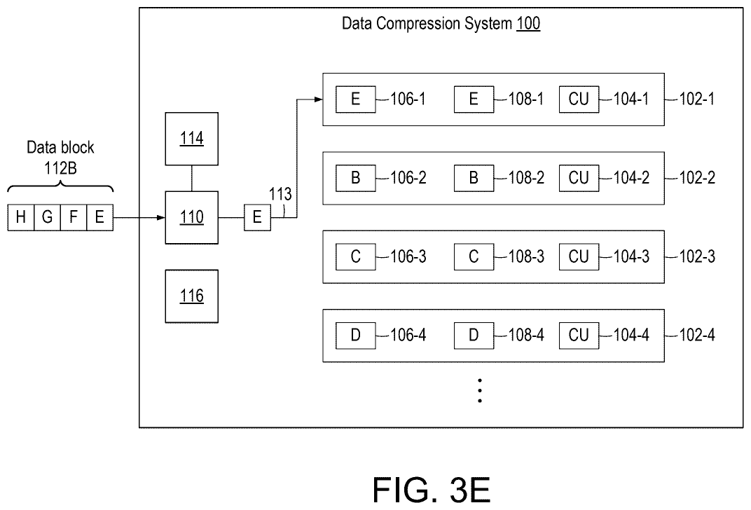

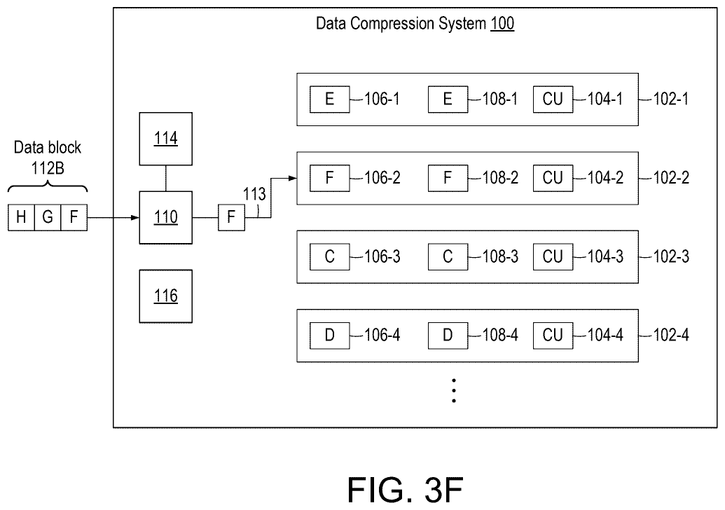

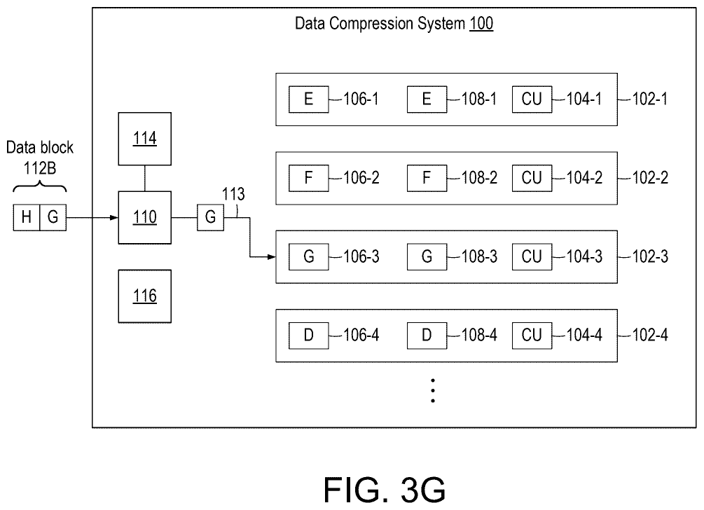

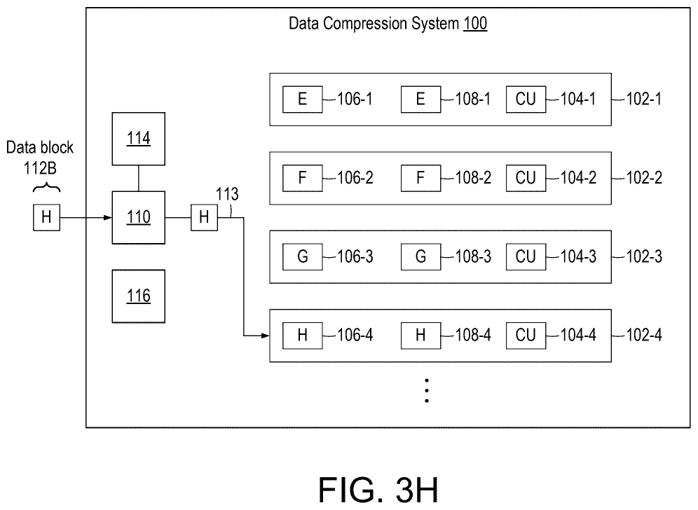

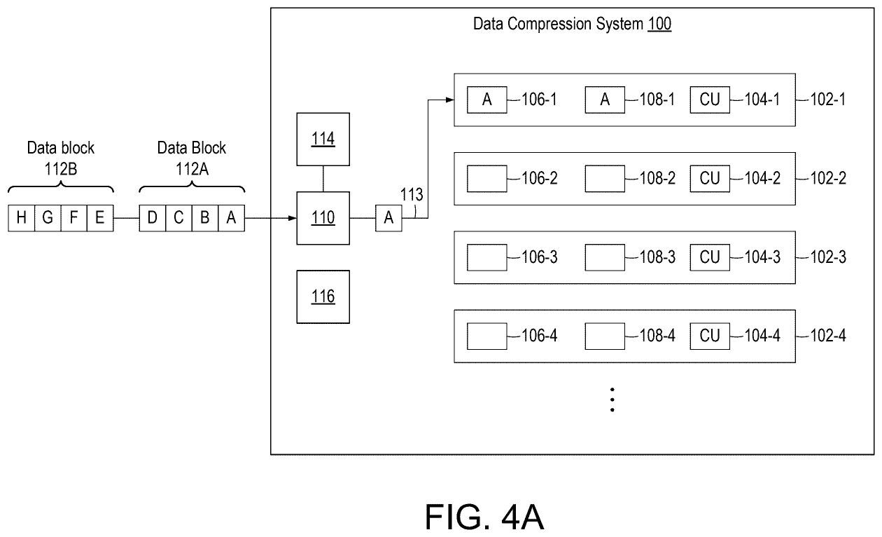

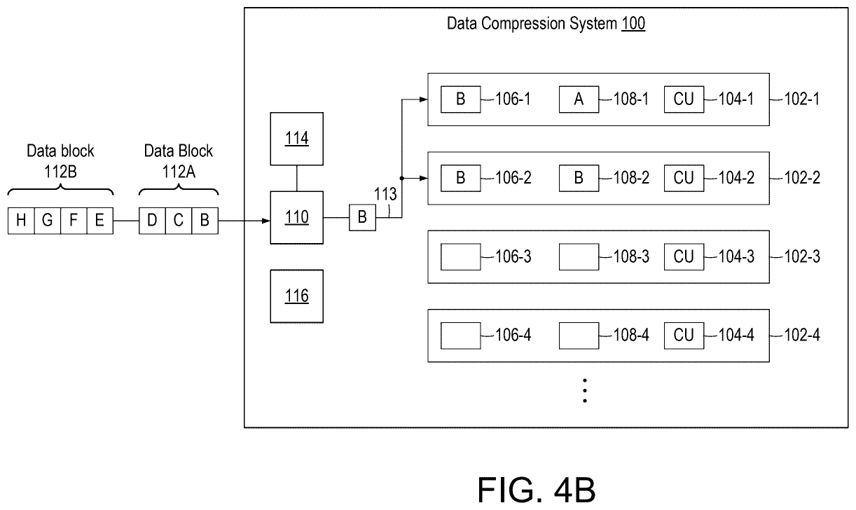

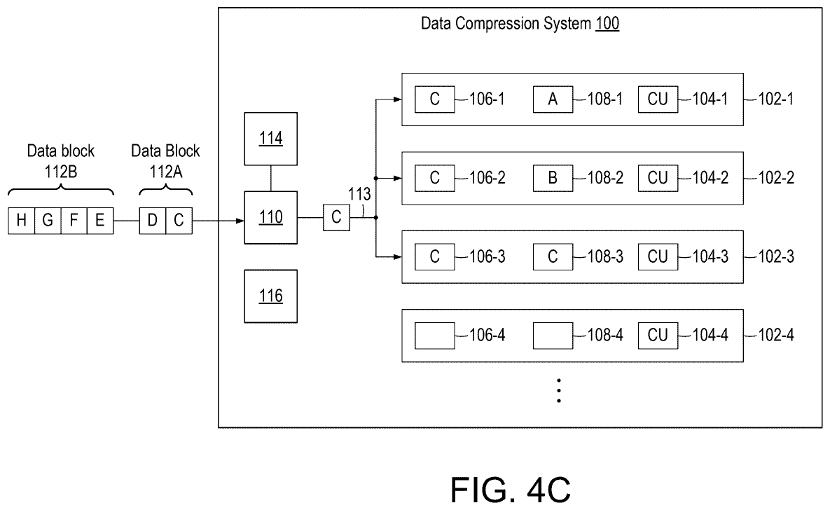

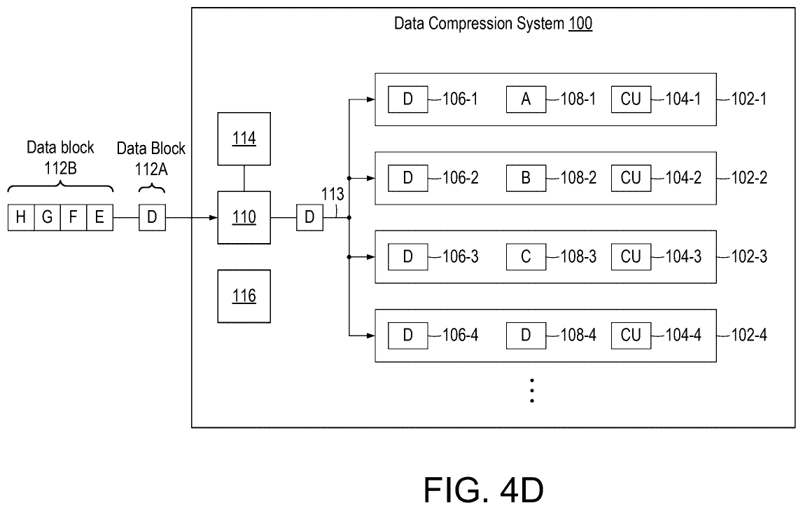

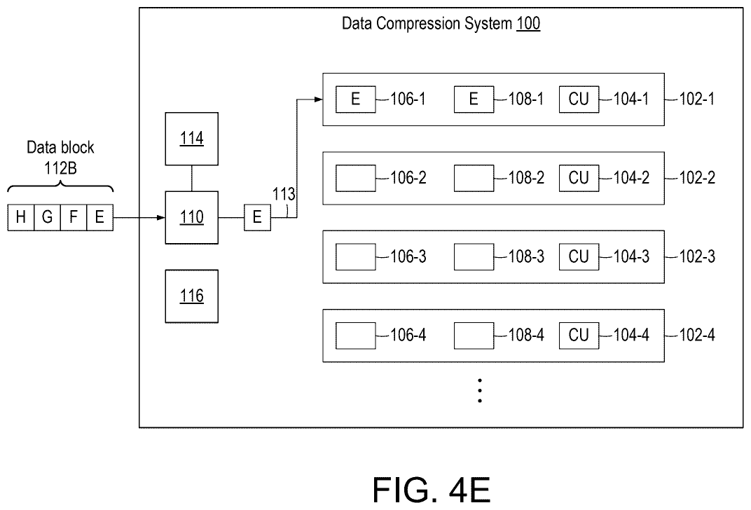

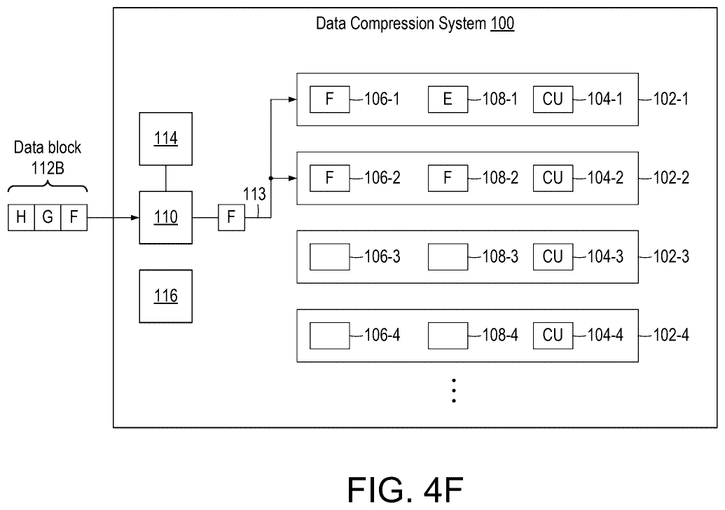

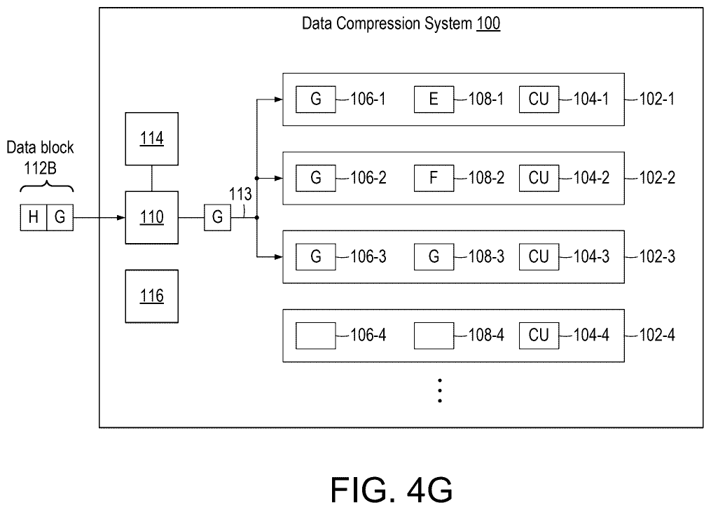

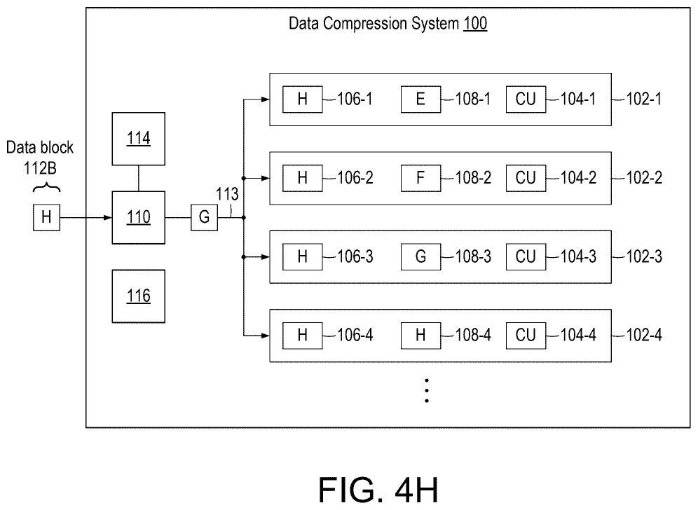

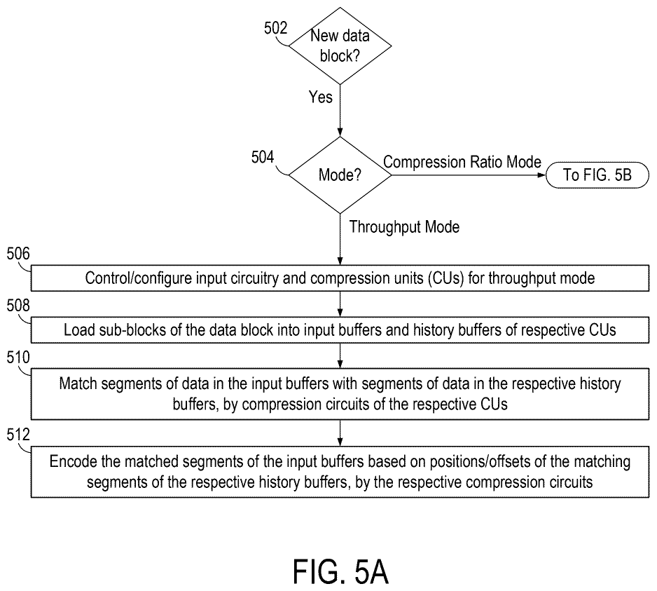

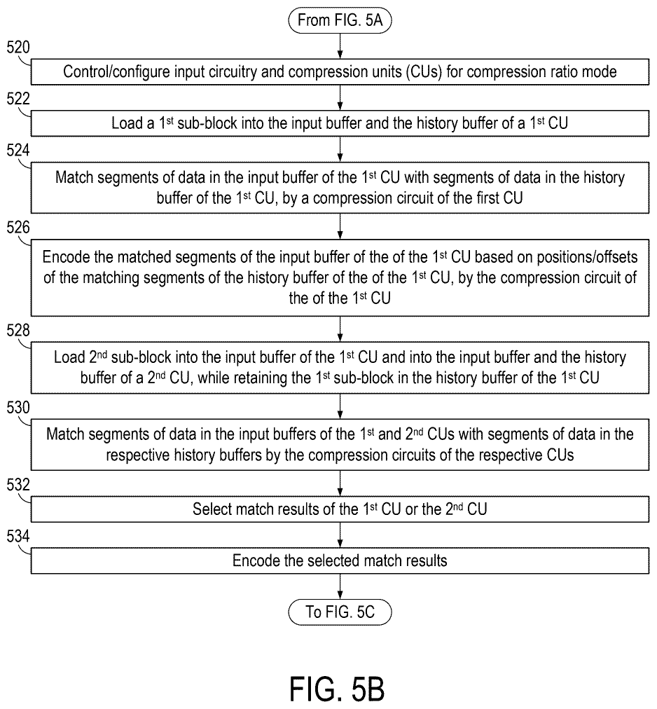

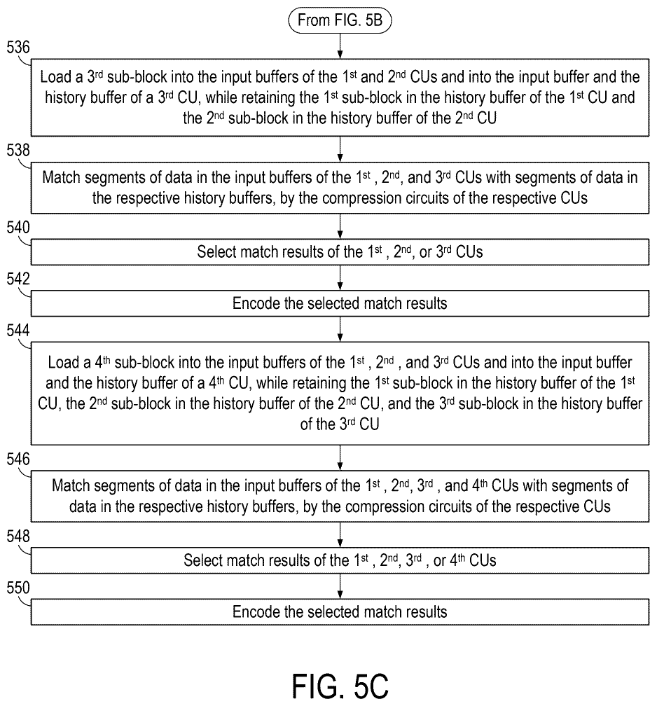

FIG. 2 depicts system 100 in the throughput mode, according to an embodiment. FIGS. 3A through 3H depict system 100 at respective stages or operations the throughput mode, according to an embodiment. FIGS. 4A through 4H depict system 100 at respective stages or operations of the compression ratio mode, according to an embodiment. In the examples of FIG. 2, FIGS. 3A through 3H, and FIGS. 4A through 4H, a first data block 112A includes sub-blocks blocks A, B, C, and D, and a second data block 112B includes sub-blocks E, F, G, and H. Data blocks 112 are not, however, limited to four sub-blocks. The examples of FIG. 2, FIGS. 3A through 3H, and FIGS. 4A through 4H, are described below with reference to FIGS. 5A, 5B, and 5C.

FIGS. 5A, 5B, and 5C depict a method 500 of compressing data, according to an embodiment. Method 500 is described below with reference to FIG. 2, FIGS. 3A through 3H, and FIGS. 4A through 4H. Method 500 is not, however, limited to the examples of FIG. 2, FIGS. 3A through 3H, or FIGS. 4A through 4H.

At 502, when input circuitry 110 receives data block 112A, processing proceeds to 504.

At 504, control circuitry 114 selects a compression mode based on user input and/or other criteria. If control circuitry 114 selects the throughput mode, processing proceeds to 506.

At 506, control circuitry 114 controls and/or configures input circuitry 110 to load input buffers 106 and history buffers 108 of CUs 102 for the throughput mode. Control circuitry 114 may also select a subset of CUs 102 (e.g., a number of CUs 102) for processing data block 112A. Control circuitry 114 may also configure input circuitry 110 to segment data block 112A into sub-blocks 113 of a desired size.

At 508, input circuitry 110 loads sub-blocks A, B, C, and D into input buffers 106 and into history buffers 108 of respective CUs 102. Input circuitry 110 may load sub-blocks A, B, C, and D into input buffers 106 and history buffers 108 of respective CUs 102 simultaneously, such as depicted in FIG. 2, and/or as the respective buffers become available.

Input circuitry 110 may load sub-blocks A, B, C, and D into input buffers 106 and history buffers 108 of consecutive CUs 102, such as depicted in FIG. 2 and in FIGS. 3A through 3D. Alternatively, input circuitry 110 may load sub-blocks A, B, C, and D into input buffers 106 and history buffers 108 of non-consecutive CUs 102 (e.g., based on availability of CUs 102).

At 510, compression circuits 104-1 through 104-4 match segments of data of the respective input buffers 106, with segments of data of the respective history buffers 108.

At 512, compression circuits 104-1 through 104-4 encode the matched segments of the respective input buffers 106 based on positions/offsets of the matching segments of the respective history buffers 108, independent of one another.

Where input circuitry 110 loads sub-blocks A, B, C, and D into input buffers 106 and history buffers 108 simultaneously, such as depicted in FIG. 2, compression circuits 104-1 through 104-4 may perform the matching at 510 and the encoding at 512 in parallel with one another.

Returning to 504, if control circuitry 114 selects the compression ratio mode, processing proceeds to 520 in FIG. 5B.

At 520, control circuitry 114 controls and/or configures input circuitry 110 to load input buffers 106 and history buffers 108 of CUs 102 for the compression ratio mode. Control circuitry 114 may also determine/select a subset of CUs 102 for compressing data block 112A. Control circuitry 114 may also configure input circuitry 110 to segment data block 112A into sub-blocks 113 of a desired size, and/or may configure depths of input buffers 106 and history buffers 108 of the selected CUs 102.

At 522, input circuitry 110 loads sub-block A into input buffer 106-1 and into history buffer 108-1 of CU 102-1, such as depicted in FIG. 4A.

At 524, compression circuit 104-1 matches segments of data of input buffer 106-1 (i.e., sub-block A), with segments of data of history buffer 108-1 (i.e., sub-block A).

At 526, compression circuit 104-1 encodes the matched segments of input buffer 106-1 based on positions/offsets of the matching segments of history buffer 108-1.

At 528, input circuitry 110 loads sub-block B into input buffers 106-1 and 106-2, and into history buffer 108-2, and history buffer 108-1 retains sub-block A, such as depicted in FIG. 4B.

At 530, compression circuit 104-1 matches segments of data of input buffer 106-1 (i.e., sub-block B) with segments of data of history buffer 108-1 (i.e., sub-block A), and compression circuit 104-2 matches segments of data of input buffer 106-2 (i.e., sub-block B) with segments of data of history buffer 108-1 (i.e., sub-block B). In other words, compression circuits 104-1 and 104-2 search for matches to segments of sub-block B across sub-blocks A and B. Searching for matches across multiple sub-blocks increases the chances of finding longer matching segments, which increase the compression ratio.

At 532, selector circuitry 116 selects match results of compression circuit 104-1 and/or compression circuit 104-2. Selector circuitry 116 may selects the longest segment matches identified by compression circuits 104-1 and 104-2.

At 534, compression circuit 104-1 and/or compression circuit 104-2 encodes the selected match results.

At 536 (FIG. 5C), input circuitry 110 loads sub-block C into input buffers 106-1, 106-2, and 106-3, and history buffer 108-3, such as depicted in FIG. 4C. In this example, history buffer 108-1 retains sub-block A, and history buffer 108-2 retains sub-block B.

At 538, compression circuit 104-1 matches segments of data of input buffer 106-1 (i.e., sub-block C) with segments of data of history buffer 108-1 (i.e., sub-block A), compression circuit 104-2 matches segments of data of input buffer 106-2 (i.e., sub-block C) with segments of data of history buffer 108-2 (i.e., sub-block B), and compression circuit 104-3 matches segments of data of input buffer 106-3 (i.e., sub-block C) with segments of data of history buffer 108-3 (i.e., sub-block C). In other words, compression circuits 104-1, 104-2, and 104-3 search for matches to segments of sub-block C across sub-blocks A, B, and C.

At 540, selector circuitry 116 selects match results of one or more of compression circuits 104-1, 104-2, and 104-3 (e.g., based on matching segment lengths).

At 542, one or more of compression circuits 104-1, 104-2, and 104-3 encodes the selected match results.

At 544, input circuitry 110 loads sub-block D into input buffers 106-1, 106-2, 106-3, and 106-4, and history buffer 108-4, such as depicted in FIG. 4D. In this example, history buffer 108-1 retains sub-block A, history buffer 108-2 retains sub-block B, and history buffer 108-3 retains sub-block C.

At 546, compression circuit 104-1 matches segments of data of input buffer 106-1 (i.e., sub-block D) with segments of data of history buffer 108-1 (i.e., sub-block A), compression circuit 104-2 matches segments of data of input buffer 106-2 (i.e., sub-block D) with segments of data of history buffer 108-2 (i.e., sub-block B), compression circuit 104-3 matches segments of data of input buffer 106-3 (i.e., sub-block D) with segments of data of history buffer 108-3 (i.e., sub-block C), and compression circuit 104-4 matches segments of data of input buffer 106-4 (i.e., sub-block D) with segments of data of history buffer 108-3 (i.e., sub-block D). In other words, compression circuits 104-1, 104-2, 104-3, and 104-4 search for matches to segments of sub-block D across sub-blocks A, B, C, and D.

At 548, selector circuitry 116 selects match results of one or more of compression circuits 104-1, 104-2, 104-3, and 104-4.

At 550, one or more of compression circuits 104-1, 104-2, 104-3, and 104-4 encodes the selected match results.

Returning to 502, when input circuitry 110 receives data block 112B, processing proceeds to 504. If control circuitry 114 selects the throughput mode, processing proceeds to 506, such as described further above with respect to data block 112A.

When processing reaches 508, input circuitry 110 may load sub-blocks E, F, G, and H into input buffers 106 and history buffers 108 of respective CUs 102 simultaneously, such as described further above with reference to FIG. 2, or consecutively, such as depicted in FIGS. 3E through 3H.

If control circuitry 114 selects the compression ratio mode for data block 112B at 502, processing proceeds to 520 for processing of sub-blocks E, F, G, and H, such as depicted in FIGS. 4E through 4H.

In the examples of FIGS. 3A through 3H and FIGS. 4A through 4H, input circuitry 110 uses the same set of CUs 102 (i.e., CUs 102-1 through 102-4) for data blocks 112A and 112B. In other examples, input circuitry 110 may use different sets of CUs 102 for data blocks 112A and 112B, may use overlapping sets of CUs 102 for data blocks 112A and 112B, and/or may use differing numbers of CUs 102 for data blocks 112A and 112B.

In the preceding, reference is made to embodiments presented in this

disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A data compression system, comprising:
multiple compression units (CUs), each comprising a compression circuit, an input buffer, and a history buffer; and
input circuitry configured to load the input buffers and the history buffers with sub-blocks of a data block;
wherein the compression circuits are configured to identify segments of the sub-blocks of the corresponding input buffers that match segments of the sub-blocks of the corresponding history buffers; and
wherein one or more of the compression circuits is further configured to encode the identified segments based on positions of the matching segments within the respective history buffers.

2. The data compression system of claim 1, wherein:
the input circuitry is further configured to load each of the sub-blocks into a respective one of the input buffers and the corresponding history buffer; and
the compression circuits are further configured to encode the identified segments of the corresponding input buffers based on the positions of the matching segments within the corresponding history buffers, independent of one another.

3. The data compression system of claim 2, wherein the input circuitry is further configured to:
load the input buffer and the history buffer of a first one of the CUs with a first one of the sub-blocks in a first operation; and
load the input buffer and the history buffer of a second one of the CUs with a second one of the sub-blocks in a second operation subsequent to the first operation.

4. The data compression system of claim 1, further comprising selection circuitry, wherein:
the input circuitry is further configured to load the history buffers with respective ones of the sub-blocks, and to load one of the sub-blocks into each of the corresponding input buffers;
the selection circuitry is configured to select match results of one or more of the compression circuits for encoding; and
one or more of the compression circuits is further configured to encode the selected match results.

5. The data compression system of claim 1, further comprising selection circuitry, wherein the input circuitry is further configured to:
load a first one of the input buffers and a corresponding first one of the history buffers with a first one of the sub-blocks in a first operation; and
load the first input buffer, a second one of the input buffers, and a corresponding second one of the history buffers with a second one of the sub-blocks in a second operation subsequent to the first operation.

6. The data compression system of claim 1, wherein the data compression system is operable in multiple selectable data compression modes that comprise:
a throughput mode in which the input circuitry is further configured to load the sub-blocks into respective ones of the input buffers and the corresponding history buffers; and
a compression ratio mode in which the input circuitry is further configured to load the history buffers with respective ones of the sub-blocks, and to load one of the sub-blocks into each of the corresponding input buffers.

7. The data compression system of claim 6, further comprising control circuitry, wherein the data compression modes further comprise:
a dynamic selection mode in which the control circuitry selects one of the throughput mode and the compression ratio mode based on a compression ratio of the data compression system and a data compression ratio threshold.

8. The data compression system of claim 1, wherein the input circuitry is further configured to:
load the input buffers and the history buffers of a first set of the CUs with sub-blocks of a first data block based on a first compression mode; and
load the input buffers and the history buffers of a second set of the CUs with sub-blocks of a second data block based on a second compression mode.

9. The data compression system of claim 8, wherein the first and second sets of CUs are configured to process the respective first and second data blocks in parallel with one another.

10. The data compression system of claim 1, further comprising control circuitry configured to control one or more of:
a number of the CUs to be used for compressing the data block;
a number of the sub-blocks;
sizes of the sub-blocks; and
depths of the input buffers and the history buffers.

11. A method, comprising:
compressing a data block with a data compression system that comprises multiple compression units (CUs), each comprising a compression circuit, an input buffer, and a history buffer, wherein the compressing comprises:
selecting one of multiple data compression modes;
loading the input buffers and the history buffers with sub-blocks of the data block;
identifying segments of the sub-blocks of the input buffers that match segments of the sub-blocks of the corresponding history buffers, by the corresponding compression circuits; and
encoding the identified segments based on positions of the matching segments within the respective history buffers, by one or more of the compression circuits.

12. The method of claim 11, wherein:
the loading comprises loading the sub-blocks into respective ones of the input buffers and the corresponding history buffers; and
the encoding comprises encoding the identified segments based on the positions of the matching segments within the respective history buffers, by the corresponding compression circuits independent of one another.

13. The method of claim 12, wherein the loading further comprises:
loading the input buffer and the history buffer of a first one of the CUs with a first one of the sub-blocks in a first operation; and
loading the input buffer and the history buffer of a second one of the CUs with a second one of the sub-blocks in a second operation subsequent to the first operation.

14. The method of claim 11, wherein:
the loading comprises loading the history buffers with respective ones of the sub-blocks, and loading one of the sub-blocks into each of the corresponding input buffers; and
the encoding comprises selecting match results of one or more of the compression circuits for encoding, and encoding the selected match results by one or more of compression circuits.

15. The method of claim 11, wherein the loading comprises:
loading the input buffers and the history buffers of a first set of the CUs with the sub-blocks of a first one of the data blocks based on a first compression mode; and
loading the input buffers and the history buffers of a second set of the CUs with sub-blocks of a second one of the data blocks based on a second compression mode.

16. The method of claim 11, wherein the loading comprises:
loading a first one of the input buffers and a corresponding first one of the history buffers with a first one of the sub-blocks in a first operation; and
loading the first input buffer, a second one of the input buffers, and a corresponding second one of the history buffers with a second one of the sub-blocks in a second operation subsequent to the first operation.

17. A system, comprising:
a host processor configured to execute an application program;
a data compression device configured to compress data associated with the application program; and
a data storage device configured to store the compressed data;
wherein the data compression device comprises multiple compression units (CUs), each comprising a compression circuit, an input buffer, and a history buffer; and
wherein the data compression device further comprises input circuitry configured to load the input buffers and the history buffers with sub-blocks of a data block based on one of multiple selectable data compression modes.

18. The system of claim 17, wherein:
the input circuitry is further configured to load each of the sub-blocks into a respective one of the input buffers and into the corresponding history buffer; and
the compression circuits are further configured to encode segments of the sub-blocks of the corresponding input buffers based on positions of matching segments of the sub-blocks of the corresponding history buffers, independent of one another.

19. The system of claim 17, further comprising selection circuitry, wherein:
the input circuitry is further configured to load the history buffers with respective ones of the sub-blocks, and to load one of the sub-blocks into each of the corresponding input buffers;
the selection circuitry is configured to select match results of one or more of the compression circuits for encoding; and
one or more of the compression circuits is further configured to encode the selected match results.

20. The system of claim 17, wherein the data compression device is operable in multiple selectable data compression modes that comprise:
a throughput mode in which the input circuitry is further configured to load the sub-blocks into respective ones of the input buffers and the corresponding history buffers; and
a compression ratio mode in which the input circuitry is further configured to load the history buffers with respective ones of the sub-blocks, and to load one of the sub-blocks into each of the corresponding input buffers.
